(19) United States
(12) Patent Application Publication
(10) Pub. No.: US 2025/0294663 A1
(43) Pub. Date: Sep. 18, 2025

(54) SYSTEMS AND METHODS FOR ARC DETECTION AND HANDLING USING IMPEDANCE DATA

(71) Applicant: Advanced Energy Industries, Inc., Denver, CO (US)

(72) Inventor: Joshua B. Pankratz, Fort Collins, CO (US)

(21) Appl. No.: 18/605,486

(22) Filed: Mar. 14, 2024

(51) Int. Cl. H05H 1/34; H05H 1/36

(52) U.S. Cl. CPC H05H 1/3473; H05H 1/36

(57) ABSTRACT

The disclosure describes a power system, a method, and an apparatus for arc handling. The power system configured for arc handling may apply power to a plasma load with a power supply, calculate an impedance of a plasma load based, at least in part, on monitoring voltage and current signals at an input of the plasma load, detect an arc in the plasma load based, at least in part, on the calculated impedance, and manage the power applied by the power supply based, at least in part, on the calculated impedance.

### FIELD

The present disclosure relates generally to power supplies. More specifically, but without limitation, the present disclosure relates to systems, methods, and apparatuses for arc detection and handling.

### BACKGROUND

In plasma processing applications arcs are known to develop when a discharge occurs between a point on a cathode where charge has accumulated and a point on the anode. If not extinguished quickly, arcs can be very detrimental to the process and the quality of the processed film. Therefore, it is imperative that arcs are detected quickly and reliably. Often, arcs are detected by monitoring the output voltage of the power supply. For instance, an arc can be detected when the output voltage of the power supply drops below a pre-defined threshold voltage. In some other cases, arcs can be detected by monitoring a slope (dV/dt) of the voltage drop and comparing it to a threshold rate of voltage drop. In yet other cases, arcs can be detected by monitoring the current. For instance, a steep or instant rise in the output current can be indicative of an arc in the plasma processing chamber. Additionally, or alternatively, if the output current exceeds a threshold current value, it can also be indicative of an arc in the plasma process.

### SUMMARY

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In some aspects, the techniques described herein relate to a method for arc handling, including: applying power to a plasma load with a power supply; calculating an impedance of a plasma load based, at least in part, on monitoring voltage and current signals at an input of the plasma load; detecting an arc in the plasma load based, at least in part, on the calculated impedance; and managing the power applied by the power supply based, at least in part, on the calculated impedance.

In some aspects, the techniques described herein relate to a method, wherein the impedance is associated with an arc impedance of the arc, the method further including: quantizing arc impedances for a plurality of arcs, including at least the arc, detected in the plasma load; and characterizing each of the plurality of arcs based, at least in part, on the quantizing.

In some aspects, the techniques described herein relate to a method, further including: identifying one or more of a source and a severity for one or more of the plurality of arcs including the arc.

In some aspects, the techniques described herein relate to a method, wherein the characterizing further includes: characterizing each of the plurality of arcs as one of a high impedance arc, a low impedance arc, or an arc associated with an inadvertent current path.

In some aspects, the techniques described herein relate to a method, wherein managing the power applied by the power supply is further based at least in part on characterizing the arc as one of a high impedance arc or a low impedance arc.

In some aspects, the techniques described herein relate to a method, wherein the high impedance arc is associated with a higher arc energy than the low impedance arc, and wherein managing the power applied by the power supply includes: shutting down the power supply for at least a first duration when the arc is a high impedance arc; and shutting down the power supply for at least a second duration when the arc is a low impedance arc, wherein the second duration is shorter than the first duration; and wherein shutting down the power supply enables a hot spot associated with the arc to be cooled, minimizes a probability of the arc re-forming, or a combination thereof.

In some aspects, the techniques described herein relate to a method, wherein the quantizing further includes: counting a number of arc occurrences for different ranges of arc impedances.

In some aspects, the techniques described herein relate to a method, wherein the plasma load includes an impedance presented to the power supply, and wherein detecting the arc further includes at least one of: determining that the impedance presented to the power supply exceeds a first threshold; and determining that a rate of change of the impedance presented to the power supply exceeds a second threshold.

In some aspects, the techniques described herein relate to a method, wherein the power supply includes one of a direct current (DC) power supply and a pulsed DC power supply.

In some aspects, the techniques described herein relate to a power system including: a power supply, wherein the power supply is configured to apply power to a plasma load; a controller coupled to the power supply, the controller including: an impedance calculation module configured to calculate an impedance of the plasma load based, at least in part, on monitoring voltage and current signals at an input of the plasma load; an arc analytics module configured to detect an arc in the plasma load based, at least in part, on the calculated impedance; an arc management module configured to manage the power applied by the power supply based, at least in part, on the calculated impedance.

In some aspects, the techniques described herein relate to a power system, wherein the impedance is associated with an arc impedance of the arc, and wherein the arc analytics module is further configured to: quantize arc impedances for a plurality of arcs, including at least the arc, detected in the plasma load; and characterize each of the plurality of arcs based, at least in part, on the quantizing.

In some aspects, the techniques described herein relate to a power system, wherein the arc analytics module is further configured to identify one or more of a source and a severity for one or more of the plurality of arcs including the arc.

In some aspects, the techniques described herein relate to a power system, wherein the characterizing further includes: characterizing each of the plurality of arcs as one of a high impedance arc, a low impedance arc, or an arc associated with an inadvertent current path.

In some aspects, the techniques described herein relate to a power system, wherein managing the power applied by the power supply is further based at least in part on characterizing the arc as one of a high impedance arc or a low impedance arc.

In some aspects, the techniques described herein relate to a power system, wherein the high impedance arc is associated with a higher arc energy than the low impedance arc, and wherein managing the power applied by the power supply includes: shutting down the power supply for at least a first duration when the arc is a high impedance arc; and shutting down the power supply for at least a second duration when the arc is a low impedance arc, wherein the second duration is shorter than the first duration; and wherein shutting down the power supply enables a hot spot associated with the arc to be cooled, minimizes a probability of the arc re-forming, or a combination thereof.

In some aspects, the techniques described herein relate to a power system, wherein the quantizing further includes: counting a number of arc occurrences for different ranges of arc impedances.

In some aspects, the techniques described herein relate to a power system, wherein the plasma load includes an impedance presented to the power supply, and wherein detecting the arc further includes at least one of: determining that the impedance presented to the power supply exceeds a first threshold; and determining that a rate of change of the impedance presented to the power supply exceeds a second threshold.

In some aspects, the techniques described herein relate to a power system, wherein the power supply includes one of a direct current (DC) power supply and a pulsed DC power supply.

In some aspects, the techniques described herein relate to a power system, wherein calculating the impedance of the plasma load includes calculating a magnitude of the impedance of the plasma load.

In some aspects, the techniques described herein relate to a non-transitory, tangible computer readable storage medium, encoded with processor readable instructions to perform a method for arc handling, the method including: applying power to a plasma load with a power supply; calculating an impedance of a plasma load, based at least in part on monitoring voltage and current signals at an input of the plasma load; detecting an arc in the plasma load based, at least in part, on the calculated impedance; and managing the power applied by the power supply based, at least in part, on the calculated impedance.

In some aspects, the techniques described herein relate to a non-transitory, tangible computer readable storage medium, encoded with processor readable instructions to perform a method for arc handling, wherein the impedance is associated with an arc impedance of the arc, the method further including: quantizing arc impedances for a plurality of arcs, including at least the arc, detected in the plasma load; and characterizing each of the plurality of arcs based, at least in part, on the quantizing.

In some aspects, the techniques described herein relate to a non-transitory, tangible computer readable storage medium, encoded with processor readable instructions to perform a method for arc handling, the method further including: identifying one or more of a source and a severity for one or more of the plurality of arcs including the arc.

In some aspects, the techniques described herein relate to a non-transitory, tangible computer readable storage medium, encoded with processor readable instructions to perform a method for arc handling, wherein the characterizing further includes: characterizing each of the plurality of arcs as one of a high impedance arc, a low impedance arc, or an arc associated with an inadvertent current path.

In some aspects, the techniques described herein relate to a non-transitory, tangible computer readable storage medium, encoded with processor readable instructions to perform a method for arc handling, wherein managing the power applied by the power supply is further based at least in part on characterizing the arc as one of a high impedance arc or a low impedance arc.

In some aspects, the techniques described herein relate to a non-transitory, tangible computer readable storage medium, encoded with processor readable instructions to perform a method for arc handling, wherein the high impedance arc is associated with a higher arc energy than the low impedance arc, and wherein managing the power applied by the power supply includes: shutting down the power supply for at least a first duration when the arc is a high impedance arc; and shutting down the power supply for at least a second duration when the arc is a low impedance arc, wherein the second duration is shorter than the first duration; and wherein shutting down the power supply enables a hot spot associated with the arc to be cooled, minimizes a probability of the arc re-forming, or a combination thereof.

In some aspects, the techniques described herein relate to a non-transitory, tangible computer readable storage medium, encoded with processor readable instructions to perform a method for arc handling, wherein the quantizing further includes: counting a number of arc occurrences for different ranges of arc impedances.

In some aspects, the techniques described herein relate to a non-transitory, tangible computer readable storage medium, encoded with processor readable instructions to perform a method for arc handling, wherein the plasma load includes an impedance presented to the power supply, and wherein detecting the arc further includes at least one of: determining that the impedance presented to the power supply exceeds a first threshold; and determining that a rate of change of the impedance presented to the power supply exceeds a second threshold.

In some aspects, the techniques described herein relate to a non-transitory, tangible computer readable storage medium, encoded with processor readable instructions to perform a method for arc handling, wherein the power supply includes one of a direct current (DC) power supply and a pulsed DC power supply.

These and other features, and characteristics of the present technology, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1A illustrates an example of a power system configured for arc detection and

handling, according to various aspects of the present disclosure.

FIG. 1B illustrates another example of a power system configured for arc detection and

handling, according to various aspects of the present disclosure.

FIG. 2 illustrates a block diagram of a power supply controller that can be used to implement one or more aspects of the present disclosure.

FIG. 3 illustrates an example of a method for arc handling, according to various aspects of the present disclosure.

FIG. 4 illustrates another example of a method for arc handling, according to various aspects of the present disclosure.

FIG. 5 illustrates another example of a method for arc handling, according to various aspects of the present disclosure.

FIG. 6 illustrates a block diagram of a computer system that may be used to implement one or more aspects of the present disclosure.

### DETAILED DESCRIPTION

Prior to describing the embodiments in detail, it is expedient to define certain terms as used in this disclosure.

The word “exemplary” is used herein to mean “serving as an example, instance, or illustration.” Any embodiment described herein as “exemplary” is not necessarily to be construed as preferred or advantageous over other embodiments. As used in the specification and in the claims, the singular form of “a,” “an,” and “the” include plural referents unless the context clearly dictates otherwise. As used herein, “coupled” means both directly or indirectly coupled unless defined otherwise.

Preliminary note: the flowcharts and block diagrams in the following Figures illustrate the architecture, functionality, and operation of possible implementations of systems, methods, and computer program products according to various embodiments of the present invention. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

Arcs are effectively a change in impedance (Z_{delta}) in the plasma process. In some circumstances, this change in impedance causes a perturbation in the process voltage and/or current, which can be detected using the power supply. Current techniques for arc detection are lacking in several regards. Specifically, arc detection and handling using existing voltage and current detection methods are limited in their ability to characterize different types of arcs and provide arc responses that are tailored to manage/handle the different types of arcs.

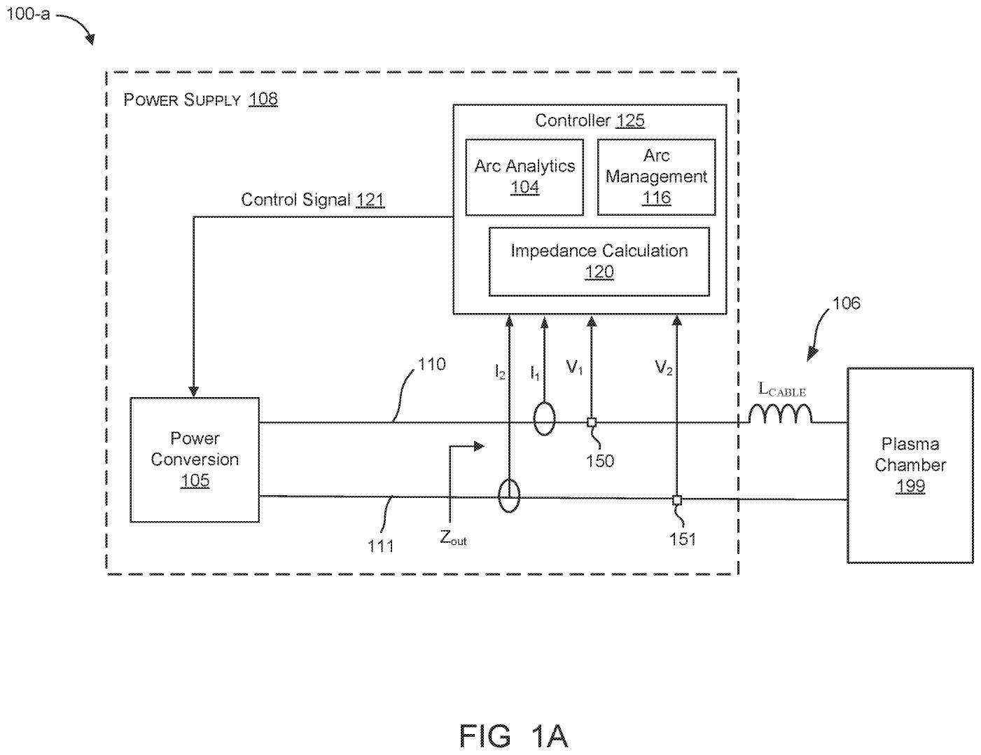

Broadly, aspects of the present disclosure generally relate to systems, methods, storage media, and apparatuses for arc detection and handling based on arc impedance data. In some embodiments, arcs can be detected by performing an impedance calculation in the power supply, for instance, in an internal controller (e.g., controller 125 in FIGS. 1A-B) of the power supply (e.g., power supply 108). In some instances, the measured impedance can be compared to an impedance threshold to determine the existence of an arc in the plasma load (or plasma chamber). In some cases, this impedance threshold may be lower than the impedance for a typical plasma process. Additionally, or alternatively, arc detection may comprise comparing the rate of change of the impedance (dZ/dt) to a rate threshold. In such cases, if the rate of change of impedance exceeds the rate threshold, it can be indicative of an arc in the plasma load. Some aspects of the disclosure are also directed to techniques for managing the power applied by the power supply to the plasma load based on the impedance calculations. For example, the controller of the power supply can be configured to provide different responses for managing/handling different types of arcs (e.g., high impedance arcs, low impedance arcs, arcs associated with an inadvertent current path, etc.). In some examples, quantization of the different arc impedances (e.g., high impedance, low impedance) can also be used to identify a source and/or severity of the arcs in the plasma load.

As used herein, the term “high impedance arc” refers to an arc associated with an arc impedance that exceeds an impedance threshold. Furthermore, the term “low impedance arc” refers to an arc associated with an arc impedance that is at or below an impedance threshold. In some circumstances, a high impedance arc may be associated with an impedance that is (1) greater than an impedance associated with a low impedance arc, and (2) lower than a typical impedance for a plasma process. In other words, the impedance associated with a high impedance arc (Z_{Arc_High}) may be between the impedance for a low impedance arc (Z_{Arc_Low}) and an impedance of a typical plasma process (Z_{Process}), i.e., Z_{Arc_Low}<Z_{Arc_High}<Z_{Process}.

Turning now to FIG. 1A, which illustrates a block diagram of a power system 100-a, according to various aspects of the disclosure. The power system 100-a comprises a power supply 108 that is connected to a plasma chamber 199 with a supply cable 106. The supply cable 106 may have an inductance, L_{CABLE}, as shown in FIG. 1A. As depicted, the power supply 108 includes power conversion circuitry 105 coupled to a first power rail 110 and a second power rail 111. The first power rail 110 may be at a higher voltage level (e.g., relative to ground) than the second power rail 111. Alternatively, the second power rail 11 may be at a higher voltage level than the first power rail 110. The power supply 108 further comprises a power supply controller 125 (or simply, controller 125), where the controller 125 includes an arc analytics module 104, an arc management module 116, and an impedance calculation module 120. The controller 125 is configured to output a control signal 121 to the power conversion circuitry 105, where the control signal 121 can be used to manage the power applied by the power conversion circuitry 105 (or the power supply 108). In some embodiments, the power supply 108 may be an example of a direct current (DC) power supply or a pulsed DC power supply. Furthermore, the power conversion circuitry 105 may include an input power source (e.g., alternating current (AC) mains) and a rectifier (e.g., half or full bridge rectifier), in some embodiments. It should be noted that the controller 125 and any of its modules (e.g., arc analytics module 104, arc management module 116, impedance calculation module 120) may include one or more devices configured through hardware, firmware, and/or software and may be specifically designed for execution of one or more of the operations of method(s) 300-500.

In some cases, the power conversion circuitry 105 applies power to a plasma load within the plasma chamber 199. In some examples, the controller 125 (or alternatively, the impedance calculation module 120) monitors current signals (e.g., current I₁, current I₂) at an input of the plasma load. The controller 125 also monitors voltage signals (e.g., a first voltage, V₁, at a first node 150 on the rail 110; a second voltage, V₂, at a second node 151 on the rail 111) at the input of the plasma load. In some cases, the impedance calculation module 120 calculates a potential difference between the first and second power rails, i.e., V₁−V₂ (or alternatively, V₂−V₁). The impedance calculation module 120 then calculates an impedance (Zₒᵤₜ) of the plasma load in the plasma chamber 199, based on the potential difference (e.g., V₁−V₂) and the information related to the current (e.g., I₁ and/or I₂). In some cases, calculating the impedance of the plasma load comprises calculating a magnitude of the impedance of the plasma load, based on monitoring voltage and current signals at the input of the plasma load.

In some embodiments, the arc analytics module 104 receives the impedance calculation data from the impedance calculation module 120 and determines whether there is an arc in the plasma chamber 199, based at least in part on the calculated impedance. In some cases, the arc analytics module 104 detects arcs in the plasma chamber 199 based on comparing the impedance (Zₒᵤₜ) to an impedance threshold, comparing the rate of the change of the impedance (i.e., dZ/dt) to a rate threshold, or a combination thereof. In some cases, the impedance is associated with an arc impedance of the arc.

In some embodiments, the arc analytics module 104 (or another module of the controller 125) is configured to quantize arc impedances for a plurality of arcs, including at least the arc, detected in the plasma chamber 199. The arc analytics module 104 may also characterize each of the plurality of arcs, based at least in part on the quantizing. In some aspects, quantizing and characterizing arcs based on their respective arc impedances can allow a high degree of flexibility with regards to how the arc management module 116 (or controller 125) manages and handles arcs. For example, aspects of the present disclosure allow different control signals 121 to be transmitted in response to detecting arcs with different arc impedances, described in further detail below.

In one non-limiting example, an arc can be characterized as one of a high impedance arc (e.g., arc impedance is above a threshold, where the threshold may be below the impedance for a typical plasma process), a low impedance arc (e.g., arc impedance is below a threshold), and an arc associated with an inadvertent current path (e.g., an arc to a shield). In some cases, the high impedance arc may be associated with a higher arc energy, in which case the power conversion circuitry 105 may need to be shut down for a longer duration to extinguish the arc, cool the hot spot, and/or minimize the probability of the arc re-forming. In contrast, the lower impedance arc may be associated with a lower arc energy, in which case a shorter shut down duration may suffice (i.e., before the power system 100 can resume normal activity). In some circumstances, an arc associated with an inadvertent current path may be associated with a different impedance, i.e., as compared to the high and low impedance arcs. In some instances, quantizing the arc impedances for a plurality of arcs can help identify one or more of a source and a severity for one or more of the plurality of the arcs. In this way, the present disclosure can facilitate in improving process scrap decisions by the end user, as compared to the prior art. For instance, a low impedance arc (i.e., associated with a lower arc energy) when extinguished sufficiently quickly may have a lower likelihood of damaging the workpiece (e.g., substrate, wafer, glass, etc.) in the plasma chamber 199, as compared to when the arc is a high impedance arc. In such cases, the arc impedance data can help the end user make more informed decisions regarding whether a particular workpiece should be scrapped or not, for instance, based on the arc energy (e.g., high energy arc, low energy arc) of the detected arc and/or the amount of time before the arc was extinguished, to name two non-limiting examples. Furthermore, quantizing the different arc impedances allows the arc analytics module 104 to distinguish between arcs associated with an inadvertent current path (e.g., arc to shield) and high or low impedance arcs. For example, the controller 125 (or another module of the power supply 108) can issue a preventive maintenance warning based on detecting that a particular arc is associated with an inadvertent current path, in some embodiments.

In some embodiments, artificial intelligence (AI) and/or machine learning (ML) techniques can be used to further optimize arc detection and handling, as compared to the prior art. For example, the controller 125 can store arc impedance data, voltage signal data, current signal data, etc., for previously detected arcs in non-transitory storage media. Furthermore, the controller can quantize arc impedances for the previously detected arcs and/or characterize each of the previously detected arcs based on the quantizing. In such cases, ML techniques can be employed to identify subsequent arcs, assign a category/classification to each of those arcs, and/or generate an adequate response to handle the arcs.

FIG. 1B illustrates another block diagram of a power system 100-b, according to various aspects of the disclosure. The power system 100-b implements one or more aspects of the power system 100-a described in relation to FIG. 1A. As seen, the power system 100-b includes a power supply 108 connected to a plasma chamber 199 with a supply cable 106. The supply cable 106 may have an inductance, L_{CABLE}, as shown in FIG. 1B. As depicted, the power supply 108 includes power conversion circuitry 105 coupled to a first power rail 110 and a second power rail 111, where the voltage associated with the first and second power rails is different. In one non-limiting example, the voltage associated with the first power rail 110 may be higher (e.g., relative to ground) than the voltage associated with the second power rail 111. The power supply 108 further comprises arc reaction circuitry 133 and a controller 125, where the controller 125 includes an arc analytics module 104, an arc management module 116, and an impedance calculation module 120. In some examples, the controller 125 is configured to output a control signal 121 to at least one of the power conversion circuitry 105 and the arc reaction circuitry 133, where the control signal can be used to manage the power applied by the power conversion circuitry 105 (or the power supply 108), manage/handle the detected arc (if any), or a combination thereof. In some embodiments, the power supply 108 may be an example of a direct current (DC) power supply or a pulsed DC power supply. Furthermore, the power conversion circuitry 105 may include an input power source (e.g., alternating current (AC) mains) and a rectifier (e.g., half or full bridge rectifier), in some embodiments. It should be noted that the controller 125 and any of its modules (e.g., arc analytics module 104, arc management module 116, impedance calculation module 120) may include one or more devices configured through hardware, firmware, and/or software and may be specifically designed for execution of one or more of the operations of method(s) 300-500.

In some cases, the power conversion circuitry 105 applies power to a plasma load within the plasma chamber 199. Furthermore, the impedance calculation module 120 monitors, in real-time, one or more current signals (e.g., current I₁, current I₂) at the input of the plasma load. In some other cases, the impedance calculation module 120 or controller 125 can monitor the current (13) at the input end of the plasma chamber 199, as shown in FIG. 1B. The controller 125 also monitors a plurality of voltage signals, including a first voltage (V₁) at a first node 150 on the rail 110 and a second voltage (V₂) at a second node 151 on the rail 111. In some cases, the impedance calculation module 120 calculates a potential difference between the first and second rails, i.e., V₁−V₂ (or alternatively, V₂−V₁). The impedance calculation module 120 then calculates an impedance (Zₒᵤₜ) of the plasma load in the plasma chamber 199, based on the potential difference (e.g., V₁−V₂) and the information related to the current(s) (e.g., I₁, I₂, and/or I₃). As noted above, in some cases, calculating the impedance of the plasma load comprises calculating a magnitude of the impedance of the plasma load, where calculating the magnitude of the impedance is further based on monitoring voltage and current signals at the input of the plasma load.

In some embodiments, the arc reaction circuitry 133 may be coupled between the power conversion circuitry 105 and the plasma chamber 199. Furthermore, the arc reaction circuitry 133 can be coupled to the two power rails 110 and 111, as shown in FIG. 1B. In some cases, the arc reaction circuitry 133 can be used in conjunction with the arc management module 116 of the controller 125 for arc management/handling.

In some cases, the arc reaction circuitry 133 can be implemented using a recovery filter and a voltage reversal circuit as described in co-owned U.S. Pat. No. 9,673,028 (“the '028 Patent”) entitled “Arc management with voltage reversal and improved recovery,” which is assigned to the assignee hereof and hereby expressly incorporated by reference herein. As described in the '028 Patent, an energy storage device can be energized by a power supply, where the energy storage device is configured to apply a reverse polarity voltage that has a magnitude that is at least as great as the voltage supplied to the plasma load by the power supply. Furthermore, once an arc is detected, the energy storage device applies power to the plasma load with a reverse polarity voltage that has a polarity that is opposite of the supplied voltage. The application of the reverse polarity voltage to the plasma load can help decrease the level of the current that is provided to the plasma load, thereby helping extinguish the arc and preventing the arc from reforming.

In some other cases, the arc reaction circuitry 133 can implement the arc management techniques described in co-owned U.S. Pat. No. 7,514,935 entitled “System and method for managing power supplied to a plasma chamber” and assigned to the assignee hereof and hereby expressly incorporated by reference herein.

In yet other cases, the arc reaction circuitry 133 can implement the arc management and handling techniques described in co-owned U.S. Pat. No. 8,217,299 (“the '299 Patent”) entitled “Arc recovery without over-voltage for plasma chamber power supplies using a shunt switch,” and assigned to the assignee hereof and hereby expressly incorporated by reference herein. As described in the '299 Patent, a shunt switch can be provided in parallel with an output port of the power supply, where the shunt switch can be closed for a period of time upon detecting an arc, which helps divert current away from the arc in the plasma chamber. The '299 Patent also describes a technique for overvoltage protection that involves triggering a pulse of the shunt switch to limit a voltage of an increasing voltage condition associated with the arc.

In some other cases, the arc reaction circuitry 133 can be used to implement the arc management/handling techniques described in co-owned U.S. Pat. No. 6,001,224 entitled “Enhanced reactive DC sputtering system” and assigned to the assignee hereof and hereby expressly incorporated by reference herein. For example, 'the 224 Patent describes the use of a tapped inductor that can be switched to ground to achieve substantial voltage reversal upon detecting an arc detection. Furthermore, this voltage reversal can be maintained for a sufficient duration to allow restoration of uniform charge density within the plasma prior to restoration of the initial driving condition. The '224 Patent also describes a technique for preventing arc discharges that involves periodically interrupting the supply of power and/or reversing the voltage via a timer system in the power supply. It should be noted that the arc management and handling techniques described herein are not intended to be limiting and other applicable techniques are contemplated in different embodiments.

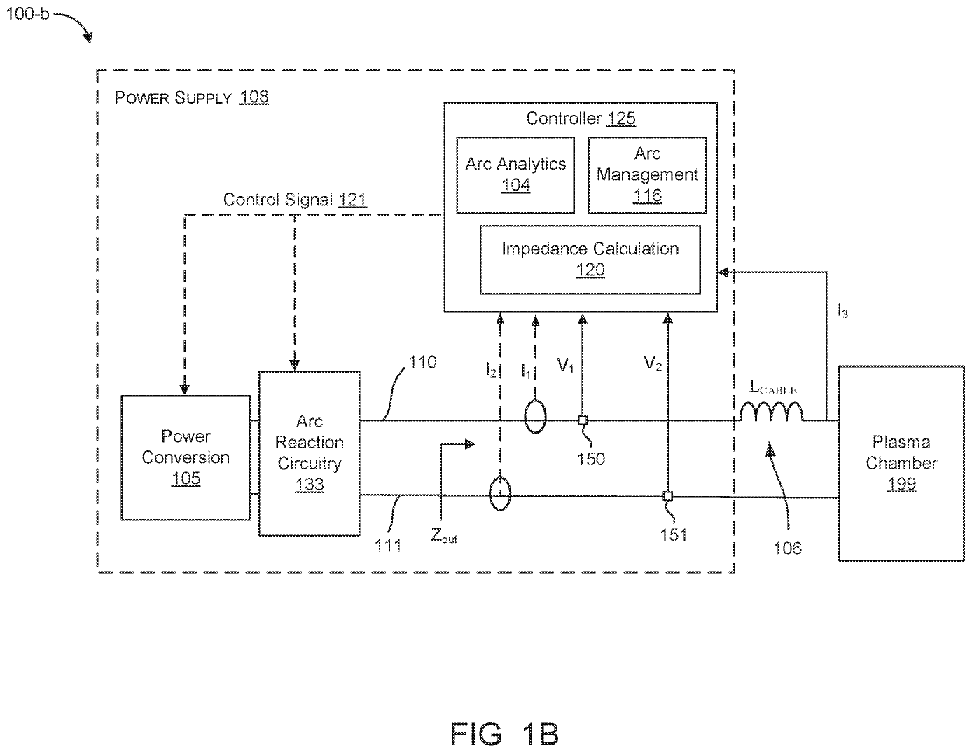

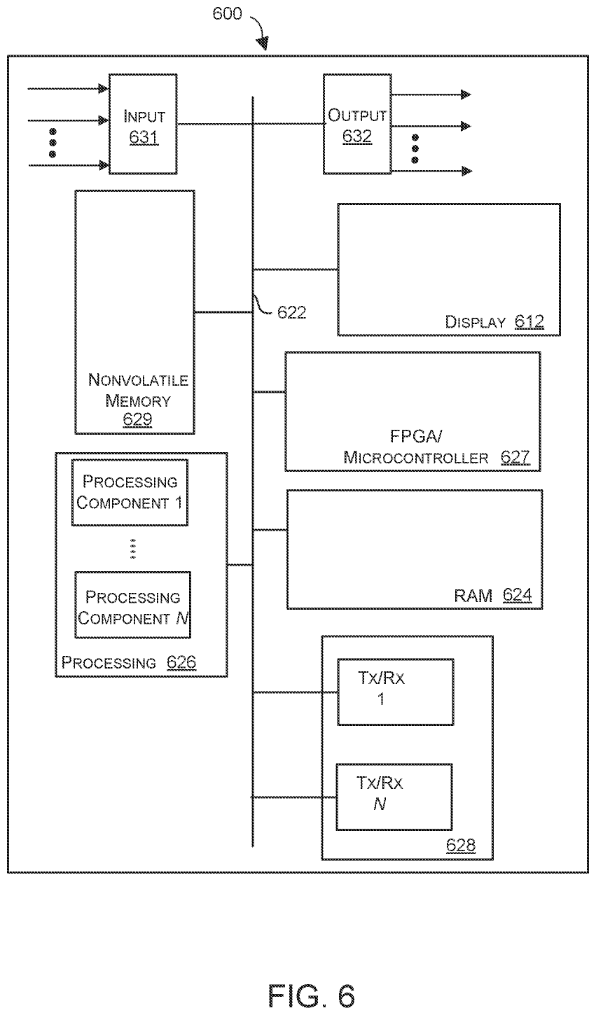

FIG. 2 illustrates a block diagram 200 of the power supply controller 125 in FIGS. 1A and/or 1B, according to various aspects of the present disclosure. As seen, the power supply controller 125 includes the arc impedance calculation module 120, arc analytics module 104, and the arc management module 116. The various modules of the power supply controller 125 may be electrically, logically, and/or communicatively coupled with each other. For example, the arc impedance calculation module 120 may be coupled to the arc analytics module 104 via a bus 261, and the arc management module and arc analytics module 104 may be coupled via another bus 262. While not shown, the arc impedance calculation module 120 may also be coupled to the arc management module 116 via a bus. In this way, the buses 261 and 262 may be utilized to exchange data between the different modules of the power supply controller 125. In some examples, the buses 261 and 262 may implement one or more aspects of the bus 622 described below in relation to FIG. 6.

The arc analytics module 104 may include an arc detection module 221 and an arc characterization module 222. The arc analytics module 104 may also store arc data 220. Alternatively, the arc analytics module 104 may be electrically and/or communicatively coupled to a data store that stores the arc data 220, where the data store may be external to the power supply controller 125. The arc data 220 may comprise information related to arcs that were previously detected in the plasma chamber (e.g., plasma chamber 199), or another plasma chamber. For example, arc impedance data may be exchanged between different power supplies connected to different plasma chambers, which can facilitate in increased accuracy in arc detection, arc characterization, etc. This in turn can help optimize arc management and handling, as compared to the prior art.

In some cases, the arc impedance calculation module 120 calculates an impedance (Z_{OUT}) of a plasma load using voltage and current measurements, as previously described in relation to FIGS. 1A and/or 1B. The arc impedance calculation module 120 then relays the impedance data to the arc analytics module 104 via bus 261. The arc detection module 221 compares the calculated impedance of the plasma load to one or more thresholds (e.g., an impedance threshold, a rate of change of impedance threshold, etc.) to determine whether the calculated impedance is indicative of an arc in the plasma chamber. In some embodiments, the arc detection module 221 may access the arc data 220 stored in the arc analytics module 104 and compare the calculated impedance to arc impedance(s) for previously detected arc(s). In some cases, the arc detection module 221 detects an arc in the plasma chamber based on one or more of (1) determining that the calculated impedance exceeds a threshold, (2) determining that the rate of change of impedance (dZ/dt) exceeds a threshold, and/or (3) determining a degree of similarity between the calculated impedance and arc impedance data for previously detected and/or confirmed arcs. In some cases, the arc detection module 221 (or alternatively, the arc characterization module 222) quantizes arc impedances for at least a portion of the arcs detected in the plasma chamber. Additionally, the arc characterization module 222 characterizes at least a portion of the arcs detected in the chamber, based on the quantizing. As noted above, characterizing the arcs may comprise characterizing each of the plurality of arcs as one of a high impedance arc (e.g., arc impedance is above a threshold), a low impedance arc (e.g., arc impedance is below the threshold), and an arc associated with an inadvertent current path (e.g., arc to shield). In some cases, the arc characterization module 222 may utilize the arc data 220 for characterizing the detected arc, where the characterizing further comprises assigning a category 225 (e.g., category 225-a, category 225-b, category 225-c) to the arc. It should be noted that the number of categories 225 depicted in FIG. 2 is not intended to be limiting and different numbers of categories are contemplated in different embodiments. Some non-limiting examples of categories 225 may include a high impedance arc, a low impedance arc, an arc associated with an inadvertent current path, an arc having an arc impedance where the rate of change of the arc impedance exceeds a rate threshold, etc. In some cases, quantizing the arc further comprises counting a number of arc occurrences for different ranges of arc impedances. In such cases, characterizing the arcs may comprise assigning a category based on the relative frequency of high to low impedance arcs. For example, a different category may be assigned to a reoccurring arc when it has more high impedance arc occurrences than low impedance arc occurrences, as compared to when it has more low impedance occurrences than high impedance arc occurrences.

In some cases, when an arc is detected, the arc analytics module 104 relays information pertaining to the category (e.g., category 225-a) to which the arc is assigned to the arc management module 116 via bus 262. The arc management module 116 then determines a response 225 (e.g., response 225-a, response 225-b, response 225-c) for managing and handling the arc. In some examples, the arc response may comprise managing the power applied by the power supply. As an example, if the detected arc is a high impedance arc, the arc response (e.g., response 225-a) may comprise shutting down the power supply for at least a first duration. In other cases, if the detected arc is a low impedance arc, the arc response (e.g., response 225-b) may comprise shutting down the power supply for at least a second duration, where the second duration is shorter than the first duration. In some examples, shutting down the power supply enables a hot spot associated with the arc to be cooled, minimizes a probability of the arc re-forming, or a combination thereof. It should be noted that, other techniques for managing/handling the arcs are contemplated in different embodiments and the examples listed herein are not intended to limit the scope and/or spirit of the present disclosure.

After determining an adequate response for handling the arc, the arc management module 116 (or alternatively, the controller 125) transmits a control signal to manage the power supply, where the control signal is linked or associated with the selected response 225.

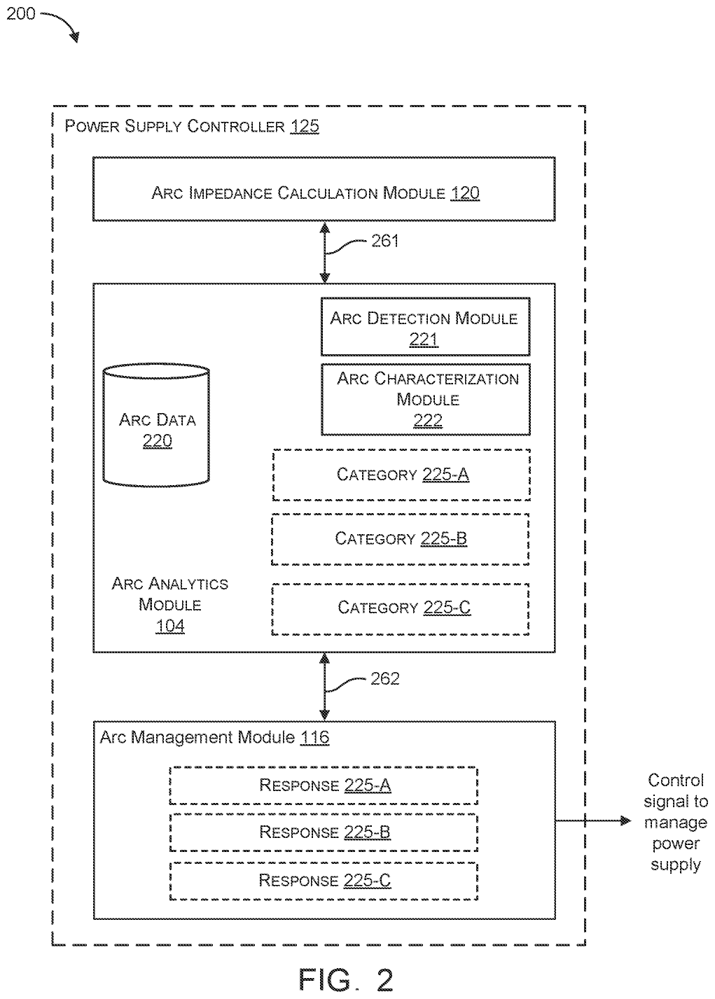

FIG. 3 illustrates an example of a method 300 for arc handling, according to various aspects of the present disclosure. The operations of method 300 presented below are intended to be illustrative. In some implementations, method 300 may be accomplished with one or more additional operations not described, and/or without one or more of the operations discussed. Additionally, the order in which the operations of method 300 are illustrated in FIG. 3 and described below is not intended to be limiting.

In some implementations, one or more operations of method 300 may be implemented in one or more processing devices (e.g., controller 125, a digital processor, an analog processor, a digital circuit designed to process information, an analog circuit designed to process information, a state machine, and/or other mechanisms for electronically processing information). The one or more processing devices may include one or more devices executing some or all of the operations of method 300 in response to instructions stored electronically on an electronic storage medium (e.g., non-transitory computer readable storage medium). The one or more processing devices may include one or more devices configured through hardware, firmware, and/or software to be specifically designed for execution of one or more of the operations of method 300.

A first operation 302 may comprise applying power to a plasma load with a power supply (e.g., power supply 108). In some cases, the plasma load is within the plasma chamber, such as plasma chamber 199 in FIG. 1A.

A second operation 304 may comprise calculating an impedance of a plasma load, where calculating the impedance is based at least in part on monitoring voltage and current signals at an input of the plasma load.

A third operation 306 may comprise detecting an arc in the plasma load based, at least in part, on the calculated impedance. As noted above, in some instances, the calculated impedance can be compared to an impedance threshold to determine the existence of an arc in the plasma load (or plasma chamber). In some cases, this impedance threshold may be lower than the impedance for a typical plasma process. Additionally, or alternatively, arc detection may comprise comparing the rate of change of the impedance (dZ/dt) to a rate threshold. In such cases, if the rate of change of impedance exceeds the rate threshold, it can be indicative of an arc in the plasma load.

A fourth operation 308 may comprise managing the power applied by the power supply based, at least in part, on the calculated impedance.

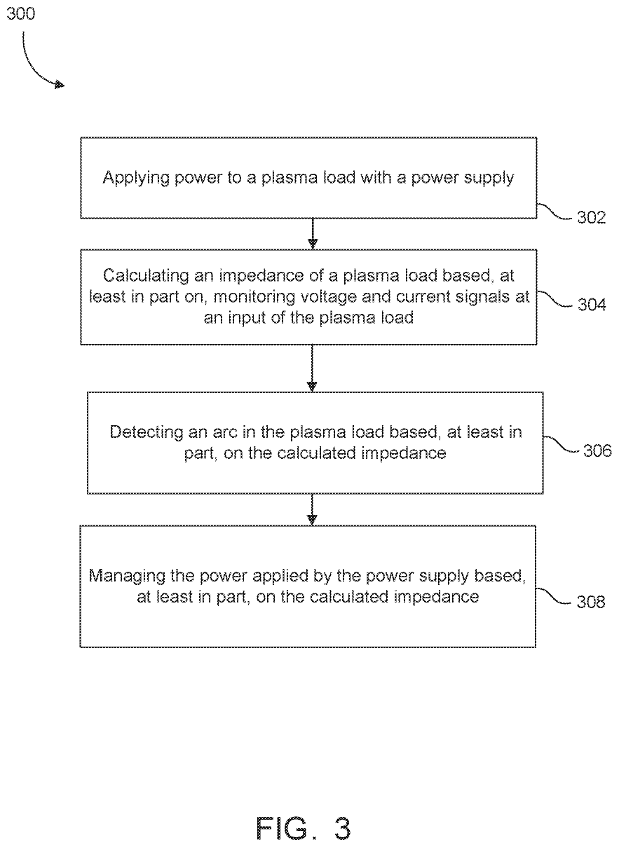

FIG. 4 illustrates an example of a method 400 for arc handling, according to various aspects of the present disclosure. The operations of method 400 presented below are intended to be illustrative. In some implementations, method 400 may be accomplished with one or more additional operations not described, and/or without one or more of the operations discussed. Additionally, the order in which the operations of method 400 are illustrated in FIG. 4 and described below is not intended to be limiting.

In some implementations, one or more operations of method 400 may be implemented in one or more processing devices (e.g., controller 125, a digital processor, an analog processor, a digital circuit designed to process information, an analog circuit designed to process information, a state machine, and/or other mechanisms for electronically processing information). The one or more processing devices may include one or more devices executing some or all of the operations of method 400 in response to instructions stored electronically on an electronic storage medium. The one or more processing devices may include one or more devices configured through hardware, firmware, and/or software to be specifically designed for execution of one or more of the operations of method 400.

A first operation 402 may comprise quantizing arc impedances for a plurality of arcs, including at least an arc, detected in the plasma chamber. In some cases, arc detection may involve calculating an impedance at an input of a plasma load in the plasma chamber, where the impedance may be calculated by monitoring voltage and current signals at the input of the plasma load, as described above in operations 304 and 306.

A second operation 404 may comprise characterizing each of the plurality of arcs based, at least in part, on the quantizing, wherein the characterizing further comprises characterizing each of the plurality of arcs as one of a high impedance arc and a low impedance arc.

In some circumstances, a high impedance arc may be associated with an impedance that is (1) greater than an impedance associated with a low impedance arc, and (2) lower than a typical impedance for a plasma process. In other words, the impedance associated with a high impedance arc (Z_{Arc_High}) may be between the impedance for a low impedance arc (Z_{Arc_Low}) and an impedance of a typical plasma process (Z_{Process}), i.e., Z_{Arc_Low}<Z_{Arc_High}<Z_{Process}.

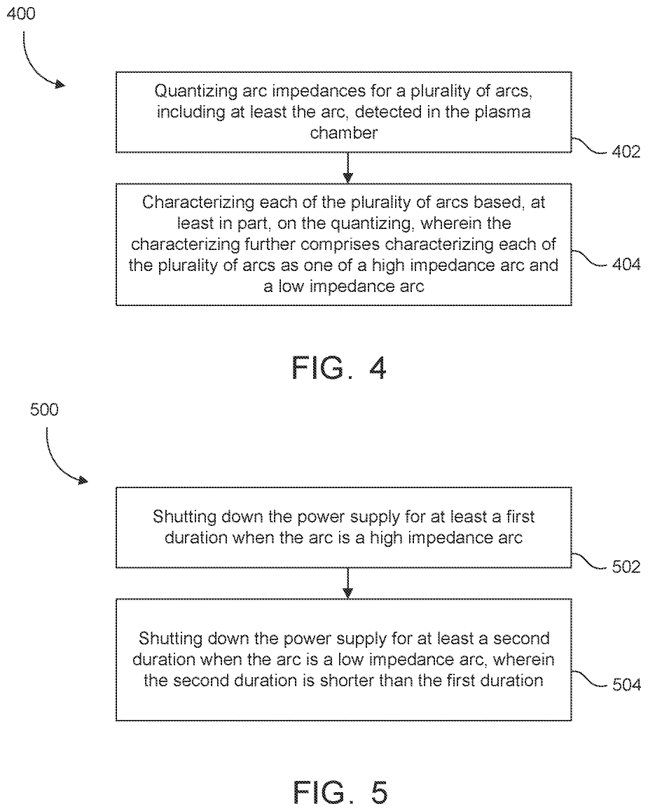

FIG. 5 illustrates an example of a method 500 for arc handling, according to various aspects of the present disclosure. The operations of method 500 presented below are intended to be illustrative. In some implementations, method 500 may be accomplished with one or more additional operations not described, and/or without one or more of the operations discussed. Additionally, the order in which the operations of method 500 are illustrated in FIG. 5 and described below is not intended to be limiting.

In some implementations, one or more operations of method 500 may be implemented in one or more processing devices (e.g., controller 125, a digital processor, an analog processor, a digital circuit designed to process information, an analog circuit designed to process information, a state machine, and/or other mechanisms for electronically processing information). The one or more processing devices may include one or more devices executing some or all of the operations of method 500 in response to instructions stored electronically on an electronic storage medium (e.g., non-transitory computer readable storage medium). The one or more processing devices may include one or more devices configured through hardware, firmware, and/or software to be specifically designed for execution of one or more of the operations of method 500.

In some cases, upon detecting an arc, the power applied by the power supply can be managed using the controller (e.g., operation 308 in FIG. 3). In some examples, characterizing the arc can comprise characterizing the arc as one of a high impedance arc or a low impedance arc (e.g., operation 404 in FIG. 4). Furthermore, managing the power applied by the power supply can be based at least in part on characterizing the arc as one of a high impedance arc or a low impedance arc. In some cases, a high impedance arc is associated with a higher arc energy than the low impedance arc.

In some cases, managing the power applied by the power supply comprises shutting down the power supply for at least a first duration when the arc is a high impedance arc (operation 502).

Alternatively, managing the power applied by the power supply comprises shutting down the power supply for at least a second duration when the arc is a low impedance arc (operation 504), where the second duration is shorter than the first duration.

FIG. 6 illustrates a block diagram of a computer system 600 that may be used to implement one or more aspects of the present disclosure, including at least a method for arc detection and handling. As shown, in this embodiment a display 612 and nonvolatile memory 629 are coupled to a bus 622 that is also coupled to random access memory (“RAM”) 624, a processing portion (which includes N processing components) 626, a field programmable gate array (FPGA) 627, and a transceiver component 628 that includes N transceivers. Although the components depicted in FIG. 6 represent physical components, FIG. 6 is not intended to be a detailed hardware diagram; thus, many of the components depicted in FIG. 6 may be realized by common constructs or distributed among additional physical components. Moreover, other existing and yet-to-be developed physical components and architectures may also be utilized to implement the functional components described with reference to FIG. 6.

A display 612 generally operates to provide a user interface for a user, and in several implementations, display 612 is realized by a touchscreen display. For example, display 612 can be used to control and interact with the components described herein. In other cases, a user may input one or more thresholds (e.g., impedance magnitude threshold, rate of change of impedance threshold) via the touchscreen display. Additionally, or alternatively, the user may be able to view real-time data related to impedance calculations, arc detection, impedance data for previously detected arcs, etc., on the display 612.

In general, nonvolatile memory 629 is non-transitory memory that functions to store (e.g., persistently store) data and machine readable (e.g., processor executable) code (including executable code that is associated with effectuating the methods described herein). In some embodiments, for example, nonvolatile memory 629 includes bootloader code, operating system code, file system code, and non-transitory processor-executable code to facilitate the execution of the methods described herein, such as method(s) 300, 400 and/or 500 in FIGS. 3-5.

In some implementations, nonvolatile memory 629 may be realized by flash memory (e.g., NAND or ONENAND memory). In other examples, other memory types may be utilized as well. Although some examples may execute the code from the nonvolatile memory 629, in other examples, the executable code in the nonvolatile memory may typically be loaded into RAM 624 and executed by one or more of the N processing components in the processing portion 626.

In operation, the N processing components in connection with RAM 624 may generally operate to execute the instructions stored in nonvolatile memory 629 to realize the functionality of one or more of the controller 125, arc analytics module 104, arc management module 116, impedance calculation module 120, and/or arc data module 220 described herein. For example, non-transitory processor-executable instructions to effectuate the methods described herein may be persistently stored in nonvolatile memory 629 and executed by the N processing components in connection with RAM 624.

Processing portion 626 may include one or more of a general-purpose processor, microcontroller, microprocessor, embedded processor, application-specific integrated circuit (ASIC) processor, video processor, digital signal processor (DSP), graphics processing unit (GPU), and other applicable processing components.

In addition, or in other examples, the field programmable gate array (FPGA) 627 may be configured to effectuate one or more aspects of the methodologies described herein. For example, non-transitory FPGA-configuration-instructions may be persistently stored in nonvolatile memory 629 and accessed by the FPGA 627 (e.g., during boot up) to configure the FPGA 627.

The input component 631 may generally operate to receive signals (e.g., voltage and current measurements, calculated impedance, rate of change of impedance, impedance threshold(s), to name a few). The output component 632 may generally operate to provide one or more digital and/or analog signals (e.g., a control signal to the power conversion circuitry 105) to effectuate operational aspects of a power system configured for arc detection and handling, and/or other system(s) described herein. In some embodiments, the computer system 600 may be used in conjunction with one or more of the controller and the power conversion circuitry described herein for applying power to a plasma load. Additionally, or alternatively, the computer system 600 may be configured to perform a method for arc detection and handling, including at least, managing power applied to the plasma load upon detecting an arc.

The depicted transceiver component 628 includes N transceiver chains, which may be used for communicating with external devices (e.g., external controllers) via wireless or wireline networks. Each of the N transceiver chains may represent a transceiver associated with a particular communication scheme (e.g., Wi-Fi, Ethernet, Profibus, etc.).

Methods 300, 400, and/or 500 and other methods of this disclosure may include other steps or variations in various other embodiments. Some or all of any of methods 300, 400, and/or 500 may be performed by or embodied in hardware, and/or performed or executed by a controller, a CPU, an FPGA, a System on Chip (SoC), a Measurement and Control Multi-Processor System on Chip (MPSoC), which may include both a CPU and an FPGA, and other elements together in one integrated SoC, or other processing device or computing device processing executable instructions, in controlling other associated hardware, devices, systems, or products in executing, implementing, or embodying various subject matter of the methods.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

It will be understood that, although the terms first, second, third, etc. may be used herein to describe various elements, components, responses, categories, and/or sections, these elements, components, responses, categories, and/or sections should not be limited by these terms. These terms are only used to distinguish one element, component, response, category, or section from another element, component, response, category, or section. Thus, a first element, component, response, category, or section discussed herein could be termed a second element, component, response, category, or section without departing from the teachings of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups but do not preclude the presence or addition of one or more other features, integers, steps, operations, elements, components, and/or groups thereof. As used herein, the term “and/or” includes any and all combinations of one or more of the associated listed items and may be abbreviated as “/”.

It will be understood that when an element or layer is referred to as being “on,” “connected to,” “coupled to,” or “adjacent to” another element or layer, it can be directly on, connected, coupled, or adjacent to the other element or layer, or intervening elements or layers may be present. In contrast, when an element is referred to as being “directly on,” “directly connected to,” “directly coupled to,” or “immediately adjacent to” another element or layer, no intervening elements or layers may be present.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

What is claimed is:

1. A method for arc handling, comprising:
applying power to a plasma load with a power supply;
calculating an impedance of a plasma load based, at least in part, on monitoring voltage and current signals at an input of the plasma load;
detecting an arc in the plasma load based, at least in part, on the calculated impedance; and
managing the power applied by the power supply based, at least in part, on the calculated impedance.

2. The method of claim 1, wherein the impedance is associated with an arc impedance of the arc, the method further comprising:
quantizing arc impedances for a plurality of arcs, including at least the arc, detected in the plasma load; and
characterizing each of the plurality of arcs based, at least in part, on the quantizing.

3. The method of claim 2, further comprising:
identifying one or more of a source and a severity for one or more of the plurality of arcs including the arc.

4. The method of claim 2, wherein the characterizing further comprises:
characterizing each of the plurality of arcs as one of a high impedance arc, a low impedance arc, or an arc associated with an inadvertent current path.

5. The method of claim 2, wherein managing the power applied by the power supply is further based at least in part on characterizing the arc as one of a high impedance arc or a low impedance arc.

6. The method of claim 5, wherein the high impedance arc is associated with a higher arc energy than the low impedance arc, and wherein managing the power applied by the power supply comprises:
shutting down the power supply for at least a first duration when the arc is a high impedance arc; and
shutting down the power supply for at least a second duration when the arc is a low impedance arc, wherein the second duration is shorter than the first duration;
and wherein shutting down the power supply enables a hot spot associated with the arc to be cooled, minimizes a probability of the arc re-forming, or a combination thereof.

7. The method of claim 2, wherein the quantizing further comprises:
counting a number of arc occurrences for different ranges of arc impedances.

8. The method of claim 1, wherein the plasma load comprises an impedance presented to the power supply, and wherein detecting the arc further comprises at least one of:
determining that the impedance presented to the power supply exceeds a first threshold; and
determining that a rate of change of the impedance presented to the power supply exceeds a second threshold.

9. The method of claim 1, wherein the power supply comprises one of a direct current (DC) power supply and a pulsed DC power supply.

10. A power system comprising:
a power supply, wherein the power supply is configured to apply power to a plasma load;
a controller coupled to the power supply, the controller comprising:
an impedance calculation module configured to calculate an impedance of the plasma load based, at least in part, on monitoring voltage and current signals at an input of the plasma load;
a first module configured to detect an arc in the plasma load based, at least in part, on the calculated impedance;
a second module configured to manage the power applied by the power supply based, at least in part, on the calculated impedance.

11. The power system of claim 10, wherein the impedance is associated with an arc impedance of the arc, and wherein the first module is further configured to:
quantize arc impedances for a plurality of arcs, including at least the arc, detected in the plasma load; and
characterize each of the plurality of arcs based, at least in part, on the quantizing.

12. The power system of claim 11, wherein the first module is further configured to identify one or more of a source and a severity for one or more of the plurality of arcs including the arc.

13. The power system of claim 11, wherein the characterizing further comprises:
characterizing each of the plurality of arcs as one of a high impedance arc, a low impedance arc, or an arc associated with an inadvertent current path.

14. The power system of claim 11, wherein managing the power applied by the power supply is further based at least in part on characterizing the arc as one of a high impedance arc or a low impedance arc.

15. The power system of claim 14, wherein the high impedance arc is associated with a higher arc energy than the low impedance arc, and wherein managing the power applied by the power supply comprises:
shutting down the power supply for at least a first duration when the arc is a high impedance arc; and
shutting down the power supply for at least a second duration when the arc is a low impedance arc, wherein the second duration is shorter than the first duration;
and wherein shutting down the power supply enables a hot spot associated with the arc to be cooled, minimizes a probability of the arc re-forming, or a combination thereof.

16. The power system of claim 11, wherein the quantizing further comprises:
counting a number of arc occurrences for different ranges of arc impedances.

17. The power system of claim 10, wherein the plasma load comprises an impedance presented to the power supply, and wherein detecting the arc further comprises at least one of:
determining that the impedance presented to the power supply exceeds a first threshold; and
determining that a rate of change of the impedance presented to the power supply exceeds a second threshold.

18. The power system of claim 10, wherein the power supply comprises one of a direct current (DC) power supply and a pulsed DC power supply.

19. The power system of claim 10, wherein calculating the impedance of the plasma load comprises calculating a magnitude of the impedance of the plasma load.

20. A non-transitory, tangible computer readable storage medium, encoded with processor readable instructions to perform a method for arc handling, the method comprising:
applying power to a plasma load with a power supply;
calculating an impedance of a plasma load, based at least in part on monitoring voltage and current signals at an input of the plasma load;
detecting an arc in the plasma load based, at least in part, on the calculated impedance; and
managing the power applied by the power supply based, at least in part, on the calculated impedance.
